(19) United States
(12) Patent Application Publication
(10) Pub. No.: US 2021/0183929 A1
(43) Pub. Date: Jun. 17, 2021

(54) IMAGE SENSING DEVICE

(71) Applicant: SK hynix Inc., Icheon-si (KR)

(72) Inventor: Soon Yeol Park, Icheon-si (KR)

(21) Appl. No.: 16/925,116

(22) Filed: Jul. 9, 2020

(30) Foreign Application Priority Data
Dec. 17, 2019 (KR) 10-2019-0168712

(51) Int. Cl. H01L 27/146

(52) U.S. Cl. CPC H01L 27/14621; H01L 27/14627

(57) ABSTRACT

The image sensing device includes a pixel array that includes a plurality of unit pixels for converting incident light into an electrical signal in response to the incident light is arranged. The pixel array includes a plurality of color filters placed relative to the plurality of unit pixels and configured to filter the incident light to transmit light at predetermined wavelengths to be received by the plurality of unit pixels, a plurality of grid structures disposed between the plurality of color filters to prevent optical crosstalk from occurring between adjacent color filters, and a lens layer disposed over the color filters and the grid structure to direct the incident light to converge upon the plurality of color filters.

### CROSS-REFERENCE TO RELATED APPLICATION

This patent document claims the priority and benefits of Korean patent application No. 10-2019-0168712, filed on Dec. 17, 2019, which is incorporated by reference in its entirety as part of the disclosure of this patent document.

### TECHNICAL FIELD

The technology and implementations disclosed in this patent document generally relate to an image sensing device. BACKGROUND

An image sensor is a device for converting an optical image into electrical signals. With the recent development of automotive, medical, computer and communication industries, the demand for high-performance image sensors is increasing in various devices such as digital cameras, camcorders, personal communication systems (PCSs), game consoles, surveillance cameras, medical micro-cameras, robots, etc.

### SUMMARY

Various embodiments of the disclosed technology relate to an image sensing device for increasing light efficiency by minimizing crosstalk between contiguous pixels.

In an embodiment of the disclosed technology, an image sensing device may include a pixel array that includes a plurality of unit pixels, each unit pixel structured to convert incident light into an electrical signal in response to the incident light and electrical signals from the pixel array represent an image captured by the pixel array. The pixel array may include a plurality of color filters placed relative to the plurality of unit pixels and configured to filter the incident light to transmit light at predetermined wavelengths to be received by the plurality of unit pixels, a plurality of grid structures disposed between the plurality of color filters, and configured to prevent optical crosstalk from occurring between adjacent color filters, and a lens layer disposed over the color filters and the grid structure, and configured to direct the incident light to converge upon the plurality of color filters. The lens layer may include a plurality of main microlenses located to spatially correspond to the plurality of unit pixels, respectively, so that each main microlens directs incident light to a corresponding unit pixel and at least one edge microlens disposed offset from the main microlenses to commonly overlap at least partially with adjacent main microlenses, and configured to refract light rays incident upon the main microlenses to corresponding unit pixels to improve image sensing.

In another embodiment of the disclosed technology, an image sensing device may include a plurality of color filters formed to filter incident light to transmit light at predetermined wavelengths, a plurality of main microlenses respectively disposed over the plurality of color filters in a manner that the main microlenses are disposed to correspond to the color filters on a one to one basis, and at least one edge microlens disposed to be between and to overlap with adjacent main microlenses in a manner that the at least one edge microlens commonly overlaps at least partially with the plurality of main microlenses.

In another embodiment of the disclosed technology, an embodiment of the disclosed technology, an image sensing device may include a pixel array in which a plurality of unit pixels formed to convert incident light into an electrical signal corresponding to the incident light is arranged. The pixel array may include a plurality of color filters configured to filter out visible light from the incident light, a plurality of grid structures disposed between the plurality of color filters, and configured to prevent optical crosstalk from occurring between color filters contiguous to each other, and a lens layer disposed over the color filters and the grid structure, and configured to enable the incident light to converge upon the plurality of color filters. The lens layer may include a plurality of main microlenses, each of which is formed per unit pixel, and at least one edge microlens disposed between the main microlenses and the color filters to commonly overlap with the main microlenses contiguous to each other, and configured to refract light incident upon the main microlenses.

In another embodiment of the disclosed technology, an image sensing device may include a plurality of color filters formed to filter out visible light from incident light, a plurality of main microlenses respectively disposed over the plurality of color filters in a manner that the main microlenses are disposed to correspond to the color filters on a one to one basis, and at least one edge microlens disposed between the color filters and the main microlenses in a manner that the at least one edge microlens commonly overlaps with the plurality of main microlenses

It is to be understood that both the foregoing general description and the following detailed description of the disclosed technology are illustrative and explanatory and are intended to provide further explanation of the disclosure as claimed.

### BRIEF DESCRIPTION OF THE DRAWINGS

FIG. 1 is a block diagram illustrating an example of an image sensing device based on some implementations of the disclosed technology.

FIG. 2 is a plan view illustrating an example of lens layers of unit pixels formed in a pixel array shown in FIG. 1 based on some implementations of the disclosed technology.

FIG. 3 is a cross-sectional view illustrating an example of the unit pixels taken along the line A-A′ shown in FIG. 2 based on some implementations of the disclosed technology.

FIG. 4A is a conceptual diagram illustrating an example of a propagation direction of light incident upon an edge region of a main microlens arranged without an edge microlens based on some implementations of the disclosed technology.

FIG. 4B is a conceptual diagram illustrating an example of the propagation direction of light incident upon the edge region of the main microlens arranged with the edge microlens based on some implementations of the disclosed technology.

FIGS. 5A to 5C are cross-sectional views illustrating examples of a method for forming a lens layer shown in FIG. 3 based on some implementations of the disclosed technology.

FIGS. 6A to 6F are cross-sectional views illustrating other examples of a method for forming the lens layer shown in FIG. 3 based on some implementations of the disclosed technology.

FIG. 7 is a plan view illustrating an example of the lens layers of the unit pixels formed in the pixel array shown in FIG. 1 based on some implementations of the disclosed technology.

FIG. 8 is a plan view illustrating another example of the lens layers of the unit pixels formed in the pixel array shown in FIG. 1 based on some implementations of the disclosed technology.

FIG. 9 is a plan view illustrating still another example of the lens layers of the unit pixels formed in the pixel array shown in FIG. 1 based on some implementations of the disclosed technology.

### DETAILED DESCRIPTION

This patent document provides implementations and examples of an image sensing device that can increase the light collection efficiency of microlenses disposed over the imaging pixel array by inserting additional microlenses at the edge regions of the main microlenses such that the additional microlenses overlap with edge regions or dead zones of the main microlenses. The disclosed technology can be used in some embodiments to implement an image sensing device which can increase light efficiency by minimizing crosstalk between contiguous pixels.

Reference will now be made in detail to certain embodiments, examples of which are illustrated in the accompanying drawings. Wherever possible, the same reference numbers will be used throughout the drawings to refer to the same or similar parts. In the following description, a detailed description of related known configurations or functions incorporated herein will be omitted to avoid obscuring the subject matter.

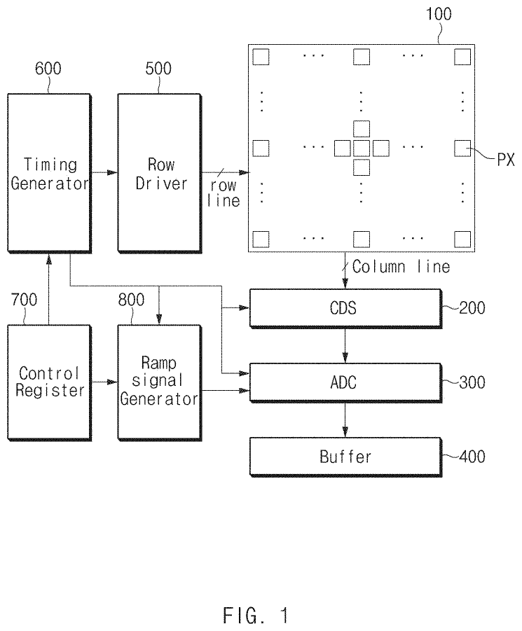

FIG. 1 is an example of a block diagram illustrating an image sensing device based on some implementations of the disclosed technology.

In some implementations, the image sensing device may include a pixel array 100, a correlated double sampler (CDS) 200, an analog-to-digital converter (ADC) 300, a buffer 400, a row driver 500, a timing generator 600, a control register 700, and a ramp signal generator 800.

The pixel array 100 may include unit pixels (PXs) consecutively arranged in rows and columns in a two-dimensional (2D) array. Each of the unit pixels (PXs) may convert incident light into an electrical signal to generate a pixel signal, which is sent to the correlated double sampler (CDS) 200 through column lines. Each unit pixel (PX) may include a photoelectric conversion element formed in a substrate. In some implementations, the unit pixels (PXs) are formed in a substrate that includes a first surface upon which light is incident and a second surface facing away from the first surface. A lens layer is arranged above a photoelectric conversion element to cause light rays to converge upon the photoelectric conversion element. The lens layer may include a specific structure which enables light incident upon the edge region of the unit pixel (PX) to converge upon the photoelectric conversion element.

The correlated double sampler (CDS) 200 may be used to remove an undesired offset value of pixels by sampling a pixel signal twice to remove the difference between these two samples. In some implementations, the correlated double sampler (CDS) 200 may hold and sample electrical image signals received from the pixels (PXs) of the pixel array 100. For example, the correlated double sampler (CDS) 200 may perform sampling of a reference voltage level and a voltage level of the received electrical image signal in response to a clock signal received from the timing generator 600, and may generate an analog signal corresponding to a difference between the reference voltage level and the voltage level of the received electrical image signal. The analog signal is sent to the analog-to-digital converter (ADC) 300 for digitalization.

The analog-to-digital converter (ADC) 300 is used to convert analog signals to digital signals. Examples of the analog-to-digital converter (ADC) 300 may include a ramp-compare type analog-to-digital converter that compares the analog pixel signal with a reference signal such as a ramp signal that ramps up or down, and a timer counts until a voltage of the ramp signal matches the analog signal. In some implementations, the analog-to-digital converter (ADC) 300 may compare a ramp signal received from the ramp signal generator 800 with a sampling signal received from the correlated double sampler (CDS) 200 to determine whether the voltage level of the ramp signal matches the voltage level of the sampling signal. The analog-to-digital converter (ADC) 300 may receive clock signals from the timing generator 600 to count the clock signals until the voltage level of the ramp signal matches the voltage level of the sampling signal, and may output a count value as a converted digital signal to the buffer 400.

The buffer 400 may temporarily store each of the digital signals received from the analog-to-digital converter (ADC) 300, and may sense and amplify each of the digital signals to output each of the amplified digital signals. Therefore, the buffer 400 may include a memory (not shown) and a sense amplifier (not shown). The memory may store the count value, which is a digital signal converted from the output signals of the plurality of unit pixels (PXs). The sense amplifier may sense and amplify each count value received from the memory.

The row driver 500 may selectively activate the pixel array 100 on a row line basis in response to an output signal of the timing generator 600. For example, the row driver 500 may generate a selection signal to select any one of the plurality of row lines.

The timing generator 600 may generate a timing signal to control the operations of the row driver 500, the correlated double sampler (CDS) 200, the analog-to-digital converter (ADC) 300, and the ramp signal generator 800.

The control register 700 may generate control signals to control the operations of the ramp signal generator 800, the timing generator 600, and the buffer 400.

The ramp signal generator 800 may generate a ramp signal to convert an image signal received from the buffer 400 to digital signals in response to a control signal received from the control register 700 and a timing signal received from the timing generator 600.

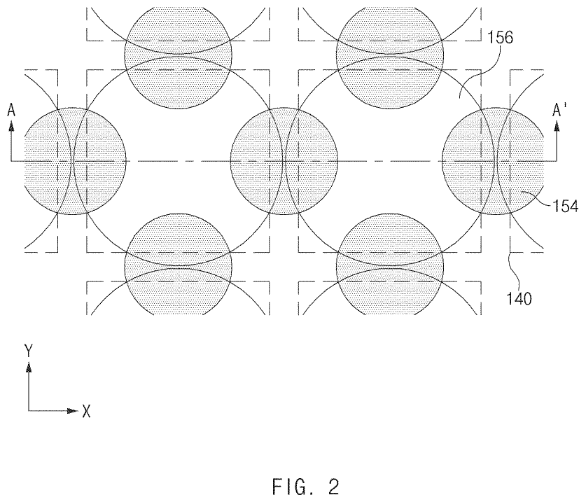

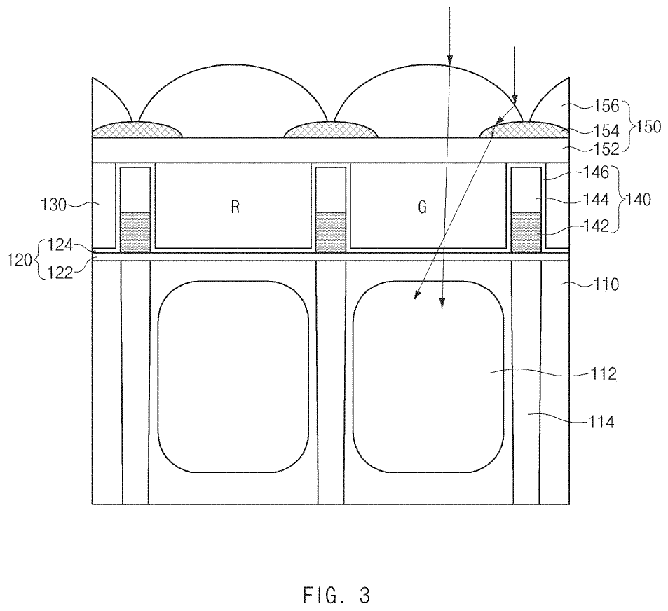

FIG. 2 is a plan view illustrating an example of lens layers of unit pixels formed in the pixel array 100 shown in FIG. 1 based on some implementations of the disclosed technology. FIG. 3 is a cross-sectional view illustrating an example of the unit pixels taken along the line A-A′ shown in FIG. 2 based on some implementations of the disclosed technology.

Referring to FIGS. 2 and 3, the pixel array 100 of the image sensing device may include a substrate 110, a buffer layer 120, a color filter layer 130, grid structures 140, and a lens layer 150.

The substrate 110 may include a semiconductor substrate having a first surface and a second surface facing away from each other.

The semiconductor substrate 110 may include a material in a monocrystalline state. In one example, the semiconductor substrate 110 may include a silicon-containing material. That is, the semiconductor substrate 110 may include a monocrystalline silicon-containing material. The semiconductor substrate 110 may include P-type impurities diffused or implanted therein. The semiconductor substrate layer 110 may include photoelectric conversion elements 112 such that each unit pixel (PX) includes one of the photoelectric conversion elements 112 isolated from adjacent photoelectric conversion elements by a device isolation film 114.

Each of the photoelectric conversion elements 112 may include an organic or inorganic photodiode. The photoelectric conversion element 112 may include impurity regions vertically stacked in the substrate 110. For example, each of the photoelectric conversion elements 112 may include a photodiode in which an N-type impurity region and a P-type impurity region are vertically stacked on top of one another. The N-type impurity region and the P-type impurity region may be formed by ion implantation. The device isolation film 114 may include a deep trench isolation (DTI) structure.

The buffer layer 120 may operate as a planarization layer for planarization of the layers formed over the first surface of the substrate 110. In addition, the buffer layer 120 may operate as an anti-reflection film that allows incident light received through the lens layer 150 and the color filter layers 130 to transmit to the photoelectric conversion elements 112. The buffer layer 120 may include a multilayer structure formed by stacking different materials having different refractive indices. For example, the buffer layer 120 may include a multilayer structure formed by stacking a nitride film 122 and an oxide film 124 on top of one another. The nitride film 122 may include a silicon nitride film (SiₓN_{y}, where each of ‘x’ and ‘y’ is a natural number) or a silicon oxide nitride film (SiₓO_{y}N_{z}, where each of ‘x’, ‘y’, and ‘z’ is a natural number). The oxide film 124 may include a monolayer structure or a multilayer structure formed by stacking oxide films. The oxide film 124 may include at least one of an undoped silicate glass (USG) film and an ultra low temperature oxide (ULTO) film. The oxide film 124 may be formed simultaneously with the capping film 146 of the grid structure 140. For example, the oxide film 124 may be formed of the same material as the capping film 146 of the grid structure 140, and the oxide film 124 and the capping film 146 may be simultaneously formed through the same deposition process.

The color filter layer 130 may include optical filters located above the photoelectric conversion elements 112 to filter the light to be detected by the photoelectric conversion elements 112. In some implementations, the color filter layer 130 may transmit visible light at a certain wavelength while blocking light at other wavelengths. The color filter layer 130 may include a plurality of color filters. Each unit pixel (PX) includes at least one color filter structured to fill the lower parts of the gaps between the grid structures 140. The color filter layer 130 may include a plurality of red color filters (Rs), a plurality of green color filters (Gs), and a plurality of blue color filters (Bs). Each red color filter (R) may transmit only red light from among RGB lights of visible light. Each green color filter (G) may transmit only green light from among RGB lights of visible light. Each blue color filter (B) may transmit only blue light from among RGB lights of visible light. In an implementation, the red color filters (Rs), the green color filters (Gs), and the blue color filters (Bs) may be arranged in a Bayer pattern. In another implementation, the color filter layer 130 may include a plurality of cyan color filters, a plurality of yellow color filters, and a plurality of magenta color filters.

The grid structures 140 may be arranged at intervals between adjacent color filters to prevent optical crosstalk from occurring between the color filters. In an example implementation, the grid structure 140 may be formed in a hybrid structure that includes a metal layer 142, a low refractive index material layer such as an air layer 144 disposed over the metal layer 142, and a capping film 146. The capping film 146 may be an outermost layer of the grid structure 140 structured to cover the metal layer 142 and the air layer 144. The capping film 146 may be formed to extend to a lower portion of the color filter layers 130. In this case, the capping film 146 formed below the color filter layers 130 may be used as a portion 124 of the buffer layer 120. In another example implementation, the grid structures 140 can also be formed without including the air layer.

The lens layer 150 may be formed over the color filter layers 130 and the grid structures 140 to enable incident light to converge upon color filters of the color filter layers 130. The lens layer 150 may include an over-coating layer 152, an edge microlens 154, and a main microlens 156.

The over-coating layer 152 may operate as a planarization layer for planarization of the layers formed by the grid structure 140 and the color filter layer 130. It is difficult to control a thickness (height) of the color filter layer 130 and a thickness of the grid structure 140, rendering the surface of the resultant structure uneven. The over-coating layer 152 may be formed over the color filter layer 130 and the grid structure 140 to provide an even surface for the subsequently formed microlens layers.

In some implementations, the over-coating layer 152 may be formed of the same materials as those of the main microlens 156.

For example, the over-coating layer 152 may include a photoresist material or an oxide film.

The disclosed technology may be implemented in some embodiments to provide an image sensing device that can increase the light collection efficiency of microlenses disposed over the imaging pixel array by inserting additional microlenses (e.g., edge microlens 154) at the edge regions of the main microlenses (e.g., main microlens 156).

The edge microlens 154 may refract light rays incident upon the edge region of the main microlens 156 to direct the refracted lights toward the photoelectric conversion element 112 of the corresponding unit pixel.

When viewed in a vertical plane, the edge microlens 154 may be formed between the main microlens 156 and the over-coating layer 152. For example, the edge microlens 154 may be formed between the main microlens 156 and the over-coating layer 152 such that the edge microlens 154 can vertically overlap with the edge region of the main microlens 156. Each of the edge microlenses 154 may be formed in a dome shape that has a flat bottom surface and a convex top surface having a curved profile.

When viewed in a horizontal plane, the edge microlenses 154 may be formed in a circular shape, and the center portion of the edge microlens 154 may be located at a boundary region between adjacent main microlenses 156 in a manner that one edge microlens 154 can overlap the edge regions of adjacent main microlenses 156.

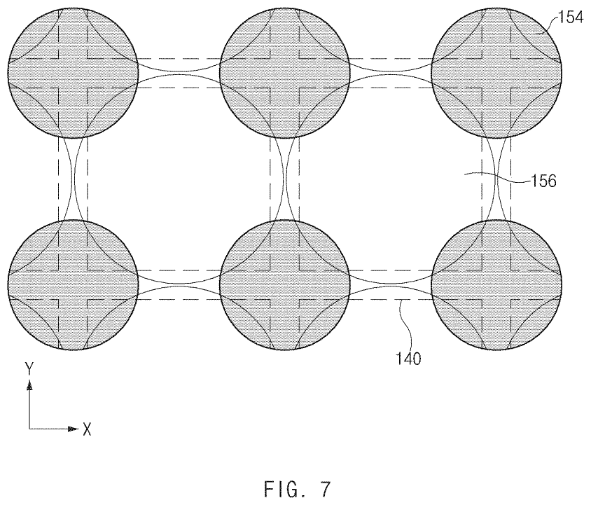

In an implementation, an edge microlens 154 can be arranged at a boundary region between two adjacent main microlenses 156. For example, the edge microlenses 154 may be spaced apart from each other by a predetermined distance in a first direction (e.g., X-axis direction) and a second direction (e.g., Y-axis direction) perpendicular to the first direction in a manner that the grid structure 140 disposed between neighboring color filters can vertically overlap with the center portion of the edge microlens 154. That is, one edge microlens 154 may overlap with the edge regions of two adjacent main microlenses 156. In another implementation, an edge microlens 154 can be arranged at a boundary region between four adjacent main microlenses 156 as will be discussed with reference to FIG. 7.

In some embodiments of the disclosed technology, the edge microlens 154 may be formed of a material having a higher refractive index than the main microlens 156.

Each unit pixel includes one main microlens 156 to direct light rays to the color filter layer 130 of the corresponding unit pixel. For example, the main microlenses 156 may respectively correspond to the unit pixels on a one to one basis, and may be formed over the over-coating layer 152 and the edge microlens 154 in the corresponding pixel region.

The main microlens 156 may be divided into a center region and edge regions surrounding the center region. An edge region of the main microlens 156 may be formed to partially overlap with the edge microlens 154. For example, edge regions formed to meet X-axis and Y-axis that pass through the center region of the main microlens 156 may be formed to overlap with the corresponding edge microlens 154. The center portion of the main microlens 156 may be formed to overlap with the center portion of the photoelectric conversion element 112.

Light rays incident upon the edge region of the main microlens 156 formed to overlap with the edge microlens 154 may be refracted toward the color filter layer 130.

The main microlens 156 may include light transmission material having a lower refractive index than the edge microlens 154. For example, the main microlens 156 may include a photoresist material or an oxide film.

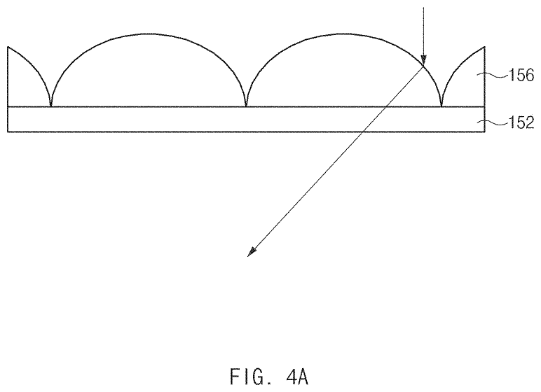

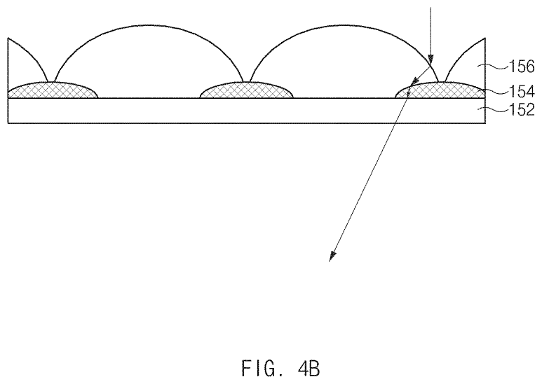

FIG. 4A is a conceptual diagram illustrating an example of the propagation direction of light incident upon the edge region of the main microlens arranged without the edge microlens based on some implementations of the disclosed technology. FIG. 4B is a conceptual diagram illustrating an example of the propagation direction of light incident upon the edge region of the main microlens arranged with the edge microlens based on some implementations of the disclosed technology.

Functions and operations of the edge microlens based on some implementations of the disclosed technology will hereinafter be described with reference to FIGS. 4A and 4B.

Referring to FIG. 4A, if the edge microlens 154 does not exist, light incident upon the edge region of the main microlens 156 may be refracted from the surface of the main microlens 156, and the refracted light may pass through the main microlens 156 and the over-coating layer 152.

In contrast, as shown in FIG. 4B, if the edge microlens 154 is disposed below the main microlens 156, light incident upon the edge region of the main microlens 156 may be primarily refracted by the main microlens 156 and may then be secondarily refracted by the edge microlens 156.

Since the edge microlens 154 is higher in refractive index than the main microlens 156 and has a curvature, light rays refracted by the edge microlens 154 may have a smaller refraction angle than the other light rays passing through only the main microlens 156. The refraction angle of the light rays refracted by the edge microlens 154 can be adjusted depending on a refractive index of the edge microlens 154, a radius of curvature (RoC) of the edge microlens 154, and other characteristics of the edge microlens 154.

If light rays having penetrated the lens layer 150 has a small refraction angle, the degree of light scattering in the buffer layer 120 can become relatively smaller as compared to light rays having a large refraction angle. Therefore, the optical crosstalk caused by light scattering in the buffer layer 120 can be reduced, while increasing the amount of light rays converging upon the photoelectric conversion element 112.

In addition, even if the over-coating layer 152 is formed of the same materials as those of the main microlens 156, light scattering may still occur at a boundary region between the over-coating layer 152 and the main microlens 156. However, if the angle of incidence of light rays incident upon the over-coating layer 152 is reduced by the edge microlens 154, less light scattering may occur. Therefore, since the edge microlens 154 is used, the optical crosstalk caused by the over-coating layer 152 can be effectively reduced.

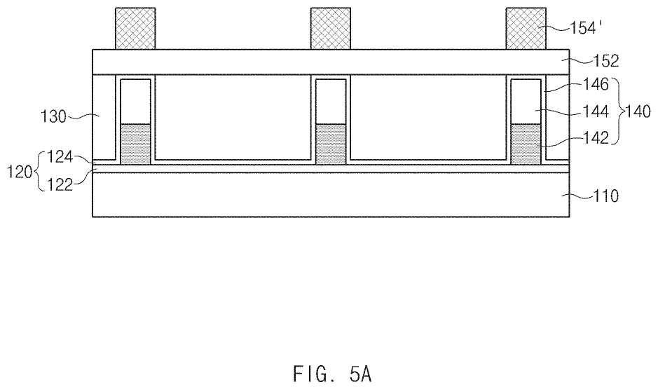

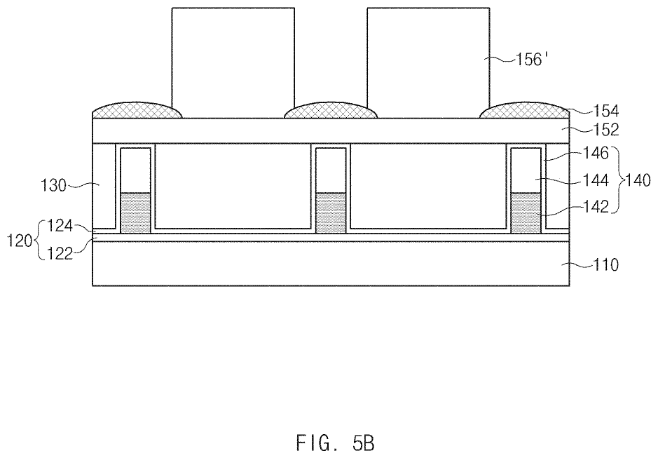

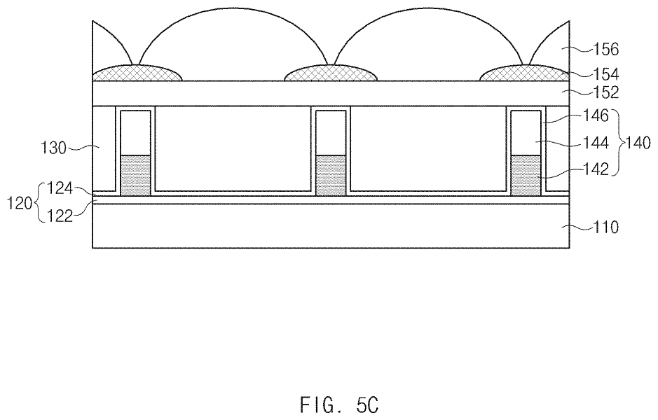

FIGS. 5A to 5C are cross-sectional views illustrating examples of a method for forming the lens layer shown in FIG. 3 based on some implementations of the disclosed technology.

Referring to FIG. 5A, the over-coating layer 152 may be formed over a lower structure including the color filter layers 130 and the grid structures 140.

The color filter layers 130 and the grid structures 140 can be formed as discussed above.

The over-coating layer 152 may be used as a planarization layer for planarization of the layers including the color filter layer 130 and the grid structure 140, and may include a photoresist material.

Subsequently, high-refractive-index material patterns 154′ may be formed in regions where the edge microlenses are to be formed, over the over-coating layer 152. The high-refractive-index material pattern 154′ may include a material having a higher refractive index than the main microlens to be formed in a subsequent process. For example, each of the high-refractive-index material patterns 154′ may include a polyimide-based resin in which microparticles (e.g., nanoparticles) having high-refractive-index materials are evenly dispersed in the form of granules within a polymer layer. In this case, the high-refractive-index material may include at least one of high-refractive-index oxide materials, for example, titanium oxide (TiO₂), tantalum oxide (TaO₂, Ta₂O₅), zirconium oxide (ZrO₂), zinc oxide (ZnO), tin oxide (SnO), aluminum oxide (Al₂O₃), lanthanum oxide (La₂O₃), cesium oxide (CeO₂), yttrium oxide (Y₂O₃), silicon oxide nitride (SiON), etc.

Referring to FIG. 5B, through a thermal reflow process on the high-refractive-index material pattern 154′, dome-shaped edge microlenses 154 may be formed over the over-coating layer 152.

Subsequently, an organic material pattern 156′ for forming the main microlens may be formed between the edge microlenses 154. For example, the organic material pattern 156′ may include a photoresist pattern.

Referring to FIG. 5C, a thermal reflow process is performed on the organic material pattern 156′, such that the dome-shaped main microlenses 156 may be formed over the over-coating layer 152 and the edge microlenses 154. In this way, the edge regions of the main microlenses 156 may be formed to overlap with the edge microlenses 154.

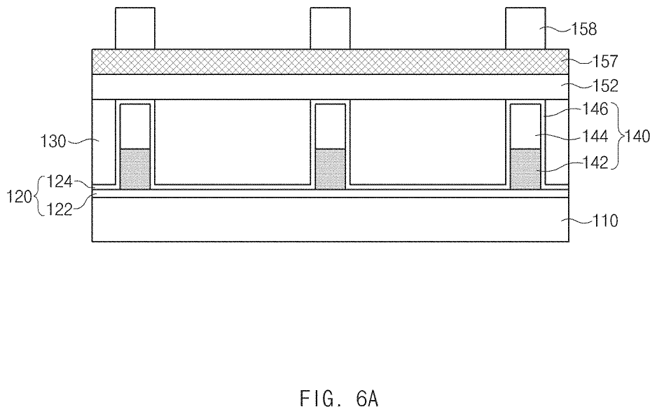

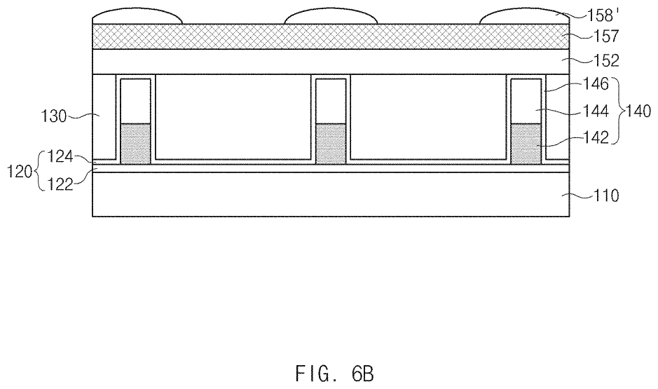

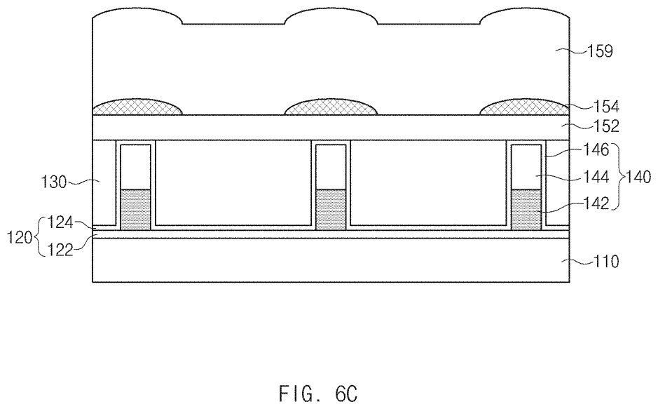

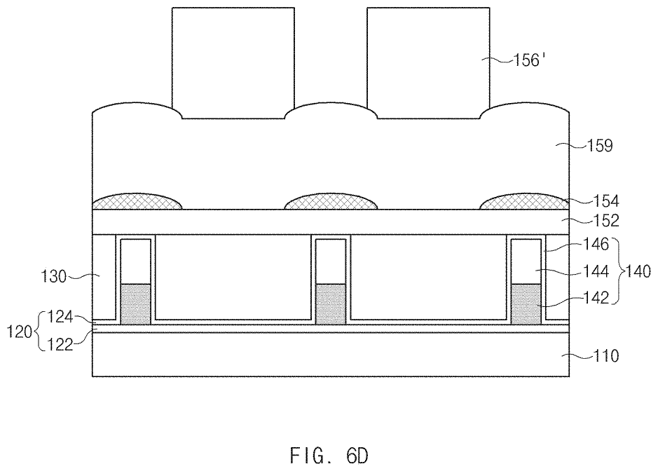

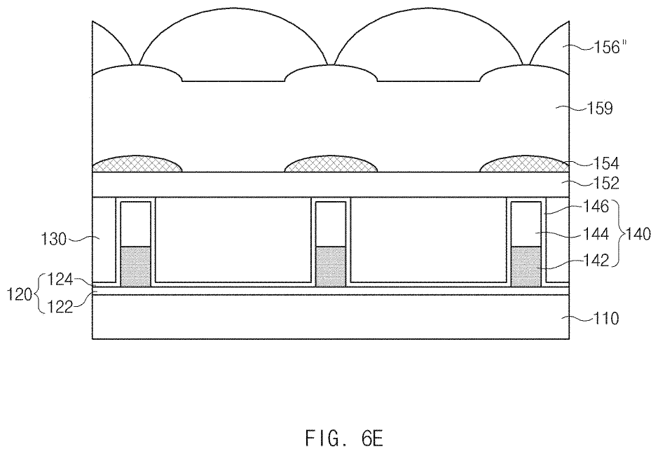

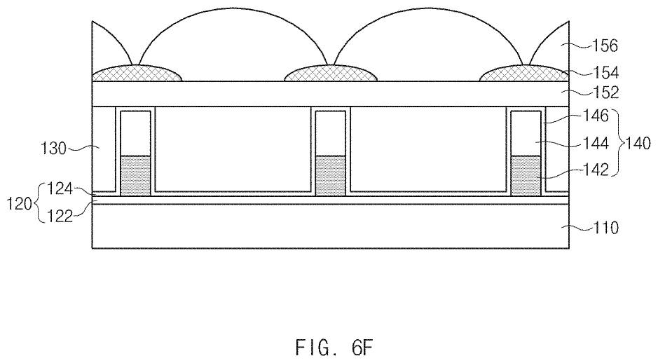

FIGS. 6A to 6F are cross-sectional views illustrating other examples of a method for forming the lens layer shown in FIG. 3 based on some implementations of the disclosed technology.

Referring to FIG. 6A, the over-coating layer 152 may be formed over a lower structure including the color filter layers 130 and the grid structures 140.

Subsequently, a high-refractive-index material layer 157 may be formed over the over-coating layer 152. The high-refractive-index material layer 157 may include at least one of high-refractive-index oxide materials, for example, titanium oxide (TiO₂), tantalum oxide (TaO₂, Ta₂O₅), zirconium oxide (ZrO₂), zinc oxide (ZnO), tin oxide (SnO), aluminum oxide (Al₂O₃), lanthanum oxide (La₂O₃), cesium oxide (CeO₂), yttrium oxide (Y₂O₃), silicon oxide nitride (SiON), etc.

Subsequently, organic material patterns 158 may be formed in regions where the edge microlenses are to be formed, over the high-refractive-index material layer 157. For example, each of the organic material patterns 158 may include a photoresist pattern.

Referring to FIG. 6B, a thermal reflow process is performed on the organic material pattern 158, such that a dome-shaped edge-lens mask pattern 158′ may be formed over the high-refractive-index material layer 157.

Referring to FIG. 6C, a lower high-refractive-index material layer 157 may be etched using the edge-lens mask patterns 158′ as an etch mask, thereby forming dome-shaped edge microlenses 154 over the over-coating layer 152.

Subsequently, an insulation layer 159 may be formed over the over-coating layer 152 and the edge microlenses 154. In this case, the insulation layer 159 may include an oxide film that has a lower refractive index than each of the edge microlenses 154.

Referring to FIG. 6D, the organic patterns 156′ may be formed in regions where the main microlenses are to be formed, over the insulation layer 159. For example, each of the organic patterns 156′ may include a photoresist pattern.

Referring to FIG. 6E, a thermal reflow process is performed on the organic patterns 156′, thereby forming dome-shaped main-lens mask patterns 156″ over the insulation layer 159.

Referring to FIG. 6F, a lower insulation layer 159 disposed below the main-lens mask pattern 156″ may be etched using the main-lens mask patterns 156″ as an etch mask, such that dome-shaped main microlenses 156 are formed over the over-coating layer 152 and the edge microlenses 154. In this case, the edge regions of the main microlenses 156 may be formed to overlap with the edge microlenses 154.

FIG. 7 is a plan view illustrating an example of the lens layers of the unit pixels formed in the pixel array shown in FIG. 1 based on some implementations of the disclosed technology.

In some implementations, the center portion of each edge microlens 154 may be located at a boundary region between the corresponding main microlenses 156 in a manner that the edge microlenses 154 can be located to span the edge regions of four contiguous main microlenses 156.

For example, each of the edge microlenses 154 may be formed in a circular dome shape in a manner that the center portion of the edge microlenses 154 can be located at a boundary region (i.e., a dead zone) between four adjacent main microlenses 156 and can partially overlap with the edge regions of the four main microlenses 156.

In this case, the center portion of the edge microlenses 154 may be formed to overlap with a specific region in which one grid structure 140 extending in the X-axis direction and another grid structure 140 extending in the Y-axis direction are arranged to cross each other.

The remaining structures other than structures of the edge microlenses shown in FIG. 7 are similar or identical to those of

FIG. 3, and as such a detailed description thereof will herein be omitted for convenience of description.

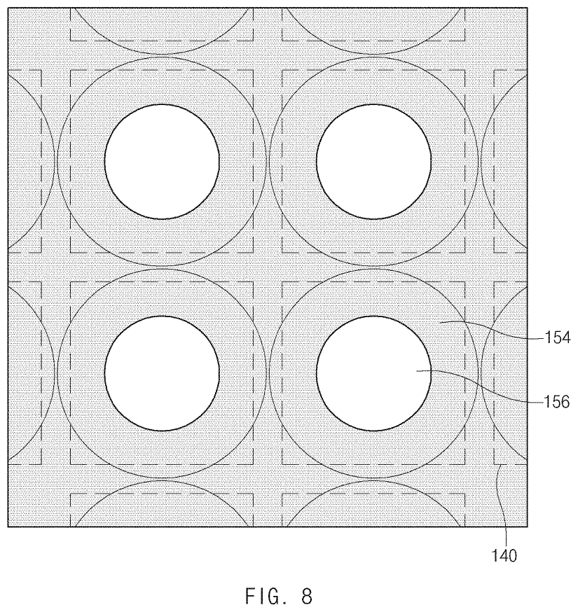

FIG. 8 is a plan view illustrating another example of the lens layers of the unit pixels formed in the pixel array shown in FIG. 1 based on some implementations of the disclosed technology.

In some implementations, each of the edge microlenses 154 may be formed to overlap the edge regions of the contiguous main microlenses 156 adjacent to each other, and may be formed in a grid shape that overlap with the main microlenses 156 except the center region of the main microlenses 156. For example, the edge microlenses 154 are formed to overlap with the dead zones in a situation in which only the center region of each of the main microlenses 156 is formed in a circular shape, such that the edge microlenses 154 can be formed in a single integrated lens shape overlapping with the edge regions (e.g., entire edge regions).

The remaining structures other than structures of the edge microlenses shown in FIG. 8 are similar or identical to those of FIG. 3 and, as such, a detailed description thereof will herein be omitted for convenience of description.

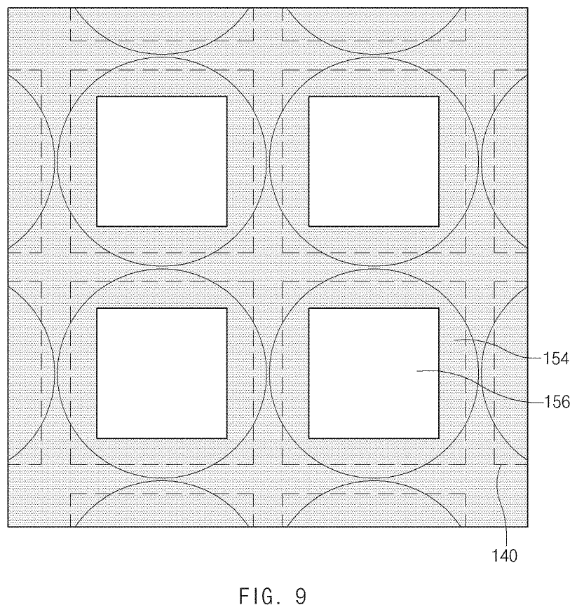

FIG. 9 is a plan view illustrating still another example of the lens layers of the unit pixels formed in the pixel array shown in FIG. 1 based on some implementations of the disclosed technology.

In some implementations, while each of the edge microlenses 154 may be formed in the same grid shape as that of the grid structure 140, each of the edge microlenses 154 may have a larger width than each of the grid structures 140. For example, the edge microlenses 154 are formed to overlap with the dead zones in a situation in which only the center region of each of the main microlenses 156 is formed in a rectangular shape, such that the edge microlenses 154 can be formed in a single integrated lens shape overlapping with the edge regions.

The remaining structures other than structures of the edge microlenses shown in FIG. 9 are similar or identical to those of FIG. 3 and, as such, a detailed description thereof will herein be omitted for convenience of description.

As is apparent from the above description, the image sensing device based on some implementations of the disclosed technology can increase the light collection efficiency by minimizing the optical crosstalk between contiguous pixels.

Those skilled in the art will appreciate that the embodiments may be carried out in other specific ways than those set forth herein without departing from the spirit and essential characteristics of the disclosure.

Although a number of illustrative embodiments have been described, it should be understood that numerous other modifications and embodiments can be devised based on what is disclosed and/or illustrated.

What is claimed is:

1. An image sensing device comprising:
a pixel array including a plurality of unit pixels, each unit pixel structured to convert incident light into an electrical signal in response to the incident light and electrical signals from the pixel array represent an image captured by the pixel array,
wherein the pixel array includes:
a plurality of color filters placed relative to the plurality of unit pixels and configured to filter the incident light to transmit light at predetermined wavelengths to be received by the plurality of unit pixels;
a plurality of grid structures disposed between the plurality of color filters, and configured to prevent optical crosstalk from occurring between adjacent color filters; and
a lens layer disposed over the color filters and the grid structure, and configured to direct the incident light to converge upon the plurality of color filters,
wherein the lens layer includes:
a plurality of main microlenses located to spatially correspond to the plurality of unit pixels, respectively, so that each main microlens directs incident light to a corresponding unit pixel; and
at least one edge microlenses disposed offset from the main microlenses to commonly overlap at least partially with adjacent main microlenses, and configured to refract light rays incident upon the main microlenses to corresponding unit pixels to improve image sensing.

2. The image sensing device according to claim 1, wherein:
each of the main microlenses includes a center region and an edge region surrounding the center region; and
the at least one edge microlens is disposed to commonly overlap at least partially with the edge regions of the adjacent main microlenses.

3. The image sensing device according to claim 2, wherein the at least one edge microlens includes:
a plurality of edge microlenses, a center portion of which is located at a boundary region of two adjacent main microlenses in a manner that the at least one edge microlens commonly overlaps at least partially with the edge regions of the two adjacent main microlenses.

4. The image sensing device according to claim 2, wherein the at least one edge microlens includes:
a plurality of edge microlenses, a center portion of which is located at a boundary region of four adjacent main microlenses in a manner that the at least one edge microlens commonly overlaps with the edge regions of the four adjacent main microlenses.

5. The image sensing device according to claim 2, wherein the at least one edge microlens includes:
a single edge microlens formed to overlap at least partially with the edge regions of the main microlenses and a plurality of dead zones disposed between the main microlenses.

6. The image sensing device according to claim 1, wherein the at least one edge microlens is formed in a circular dome shape in which a center portion is disposed to overlap at least partially with the grid structure disposed between the contiguous color filters.

7. The image sensing device according to claim 1, wherein:
a center portion of the at least one edge microlens is formed in a circular dome shape in a manner that the center portion is formed to overlap with a region in which a grid structure extending in an X-axis direction and another grid structure extending in a Y-axis direction are arranged to cross each other.

8. The image sensing device according to claim 1, wherein:
each of the main microlenses includes a center region and an edge region surrounding the center region; and
the at least one edge microlens is formed to partially overlap with the edge regions of the adjacent main microlenses.

9. The image sensing device according to claim 1, wherein the lens layer further includes:
an over-coating layer disposed between the edge microlenses and the color filters and between the main microlenses and the color filters.

10. The image sensing device according to claim 1, wherein the at least one edge microlens includes a material that has a higher refractive index than each of the main microlenses.

11. The image sensing device according to claim 1, wherein each of the grid structures includes:
a metal layer;
an air layer disposed over the metal layer; and
a capping film formed to cap or cover the metal layer and the air layer.

12. The image sensing device according to claim 1, wherein:
the unit pixel includes a photoelectric conversion element configured to convert incident light into an electrical signal corresponding to the incident light; and
a center portion of each of the main microlenses is disposed to overlap at least partially with a center portion of the photoelectric conversion element.

13. An image sensing device comprising:
a plurality of color filters formed to filter incident light to transmit light at predetermined wavelengths;
a plurality of main microlenses respectively disposed over the plurality of color filters in a manner that the main microlenses are disposed to correspond to the color filters on a one to one basis; and
at least one edge microlens disposed to be between and to overlap with adjacent main microlenses in a manner that the at least one edge microlens commonly overlaps at least partially with the plurality of main microlenses.

14. The image sensing device according to claim 13, wherein the at least one edge microlens includes:
a plurality of edge microlenses formed to commonly overlap at least partially with two adjacent main microlenses.

15. The image sensing device according to claim 13, wherein the at least one edge microlens includes:
a plurality of edge microlenses formed to commonly overlap at least partially with four contiguous main microlenses.

16. The image sensing device according to claim 15, wherein:
center portions of the plurality of edge microlenses are located in dead zones disposed between the four adjacent main microlenses.

17. The image sensing device according to claim 13, wherein:
each of the main microlenses includes a center region and an edge region surrounding the center region; and
the at least one edge microlens is formed to partially overlap with the edge regions of the plurality of main microlenses.

18. The image sensing device according to claim 13, wherein the at least one edge microlens is formed in a circular dome shape.

19. An image sensing device comprising:
a plurality of photoelectric conversion elements arranged in rows and columns;
a plurality of color filters corresponding to the plurality of photoelectric conversion elements, respectively, and arranged in rows and columns over the corresponding photoelectric conversion elements, respectively;
a plurality of first microlenses corresponding to the plurality of color filters, respectively, and arranged in rows and columns over the corresponding color filters, respectively, each first microlens including a center portion and an edge portion; and
a plurality of second microlenses arranged to be between and to partially overlap with edge portions of the plurality of first microlenses so that the first microlenses and the second microlenses collectively direct different spatial portions of incident light into the plurality of photoelectric conversion elements with improved imaging operation.

20. The image sensing device according to claim 19, wherein the edge portion of the first microlens is structured to be thinner than the center portion of the first microlens and at least partially overlapping a corresponding second microlens.
